(19) United States
(12) Patent Application Publication
(10) Pub. No.: US 2018/0285311 A1
(43) Pub. Date: Oct. 4, 2018

(54) SERVER HAVING IP MINIATURE COMPUTING UNIT

(71) Applicant: PORTWELL INC., NEW TAIPEI CITY (TW)

(72) Inventor: CHI-CHIN SU, NEW TAIPEI CITY (TW)

(21) Appl. No.: 15/828,757

(22) Filed: Dec. 1, 2017

(30) Foreign Application Priority Data
Mar. 30, 2017 (TW) 106204485

(51) Int. Cl. G06F 15/16; G06F 1/18; H05K 7/20

(52) U.S. Cl. CPC G06F 15/161; G06F 1/20; H05K 7/20727; G06F 1/183

(57) ABSTRACT

A server having an IP miniature computing unit is provided. The server includes a machine body device. The machine body device includes a bottom plate. The bottom plate is provided with a plurality of electronic devices electrically connected with the bottom plate. The electronic devices include at least one power supply, at least one exchanger, and an IP miniature computing device. The exchanger is provided with a plurality of network interfaces. The IP miniature computing device includes at least one IP miniature computing unit. The IP miniature computing unit includes a motherboard. The motherboard is electrically connected with a processor, at least one SAS connector, a voltage converter, at least one storage, and at least one memory. The SAS connector is used for receiving and transmitting network signals and power. The voltage converter converts the power received by the SAS connector into a suitable voltage.

### FIELD OF THE INVENTION

The present invention relates to a server having a computing unit, and more particularly to a 3.5-inch IP miniature computing unit. The original network storage is converted into a high-density network miniature computing unit to form a high-density miniature server operated under SDN, meeting the requirements of high-density network miniature computing units for cluster servers.

### BACKGROUND OF THE INVENTION

Nowadays, the network is based on SDN (software-defined networking). SDN is a network virtualization and uses Open Flow to separate the control plane of a router from the data plane, and is implemented with software. SDN allows a network administrator, without a change of the hardware, to replan the network by means of a program in a central control manner, so that the network can control paths automatically (automation). In the new control mode, a controller of a control layer is responsible for the network administration instead of the original, providing a method for controlling the network traffic and providing a core network and an innovative good network platform. Developers can develop application software deployed in the controller. The Open Flow and the controller are configured to communicate with and issue instructions to the equipment of the data layer, and the network equipment is responsible for packet transmission. FIG. 1 illustrates a conventional storage server operated under SDN. The storage server has a machine body device 90. The machine body device 9 includes a circuit board 901 and an end plate 902 located at a front end thereof. The circuit board 901 is configured to receive electronic devices thereon and formed with a first receiving space 90A and a second receiving space 90B. The circuit board 901 is provided with a power supply 903 and a plurality of switches 904 in the first receiving space 90A. The switch 904 is provided with a plurality of network interfaces 905. The network interfaces 905 pass through corresponding windows (not numbered) of the end plate 902 to communicate with the outside. The second receiving space 90B is provided with a hard disk device 91. The hard disk device 91 includes a plurality of hard disks 911 which may be a combination of twelve 3.5-inch hard disks for carrying out storage operations. The first receiving space 90A is provided with a fan set for cooling the hard disk device 91.

In addition, the existing rack-mounted server having a height of 1 U (about 4.445 cm) includes not more than two servers. If it is a knife-style design, the server having a height of 3 U may be mounted with fourteen servers. Not all the servers need to emphasize their computing capability, so their spaces are different. Therefore, some of the servers don't reserve too much space, thereby improving the density of the server, that is, in the same space, the number of the mounted servers is increased as much as possible. Therefore, how to effectively improve the density of the server within the space is the key point to develop and to make a breakthrough.

Accordingly, the inventor of the present invention has devoted himself based on his many years of practical experiences to solve these problems and to develop a rack-mounted server having an IP miniature computing unit.

### SUMMARY OF THE INVENTION

The primary object of the present invention is to provide a server having an IP miniature computing unit, operated under SDN, which uses a 3.5-inch hard disk designed as a 3.5-inch IP miniature computing unit and provides the SGMII signal to the outside through a SAS connector, so that the 3.5-inch IP miniature computing unit may be installed to an existing IP HDD casing. The original network storage is converted into a high-density network miniature computing unit, meeting the requirements of high-density network miniature computing units for cluster servers.

Another object of the present invention is to provide a server having an IP miniature computing unit, which enables a casing having a height of 1 U to accommodate twelve 3.5-inch IP miniature computing units therein to achieve the implementation of a high-density rack-mounted server. When one of the IP miniature computing units is damaged, the loss can be reduced. It is convenient to replace the IP miniature computing unit, with excellent practicality and economy.

In order to achieve the aforesaid objects, the server of the present invention, operated under SDN (software-defined networking), comprises a machine body device. The machine body device includes a bottom plate. The bottom plate is provided with a plurality of electronic devices electrically connected with the bottom plate. The electronic devices include at least one power supply, at least one switch, and an IP miniature computing device. The switch is provided with a plurality of network interfaces. The IP miniature computing device includes at least one IP miniature computing unit. The IP miniature computing unit includes a motherboard. The motherboard is electrically connected with a processor, at least one SAS connector, a voltage converter, at least one storage, and at least one memory. The SAS connector is used for receiving and transmitting network signals and power. The voltage converter converts the power received by the SAS connector into the voltage required for all electronic components on the motherboard.

Preferably, the SAS connector of the IP miniature computing unit is a SFF-8323 SAS connector.

Preferably, the IP miniature computing unit has an external specification identical to that of a 3.5-inch hard disk.

Preferably, the server has a height of 4.445 cm.

Preferably, the IP miniature computing device includes twelve IP miniature computing units.

Preferably, the storage of the IP miniature computing unit is M.2.

Preferably, the memory of the IP miniature computing unit is DDR3 DRAM or DDR2 DRAM.

Preferably, the processor is a CPU or a GPU (graphics processor), and a heat sink is provided above the processor.

Preferably, the CPU is an Intel X86 CPU or an ARM base CPU.

Preferably, the bottom plate is provided with a circuit board and a plurality of fans thereon.

Embodiments of the present invention will now be described, by way of example only, with reference to the accompanying drawings.

### BRIEF DESCRIPTION OF THE DRAWINGS

FIG. 1 is a schematic view of a conventional storage server operated under SDN;

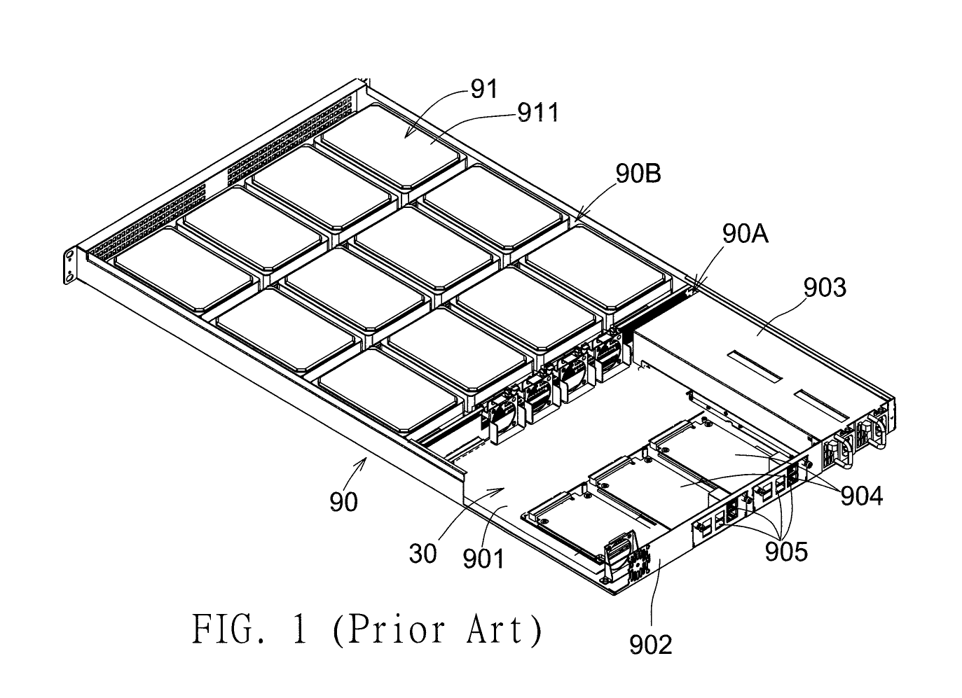

FIG. 2 is a schematic view of the present invention;

FIG. 3 is a schematic view showing the telecommunication of the IP miniature computing unit of the present invention;

FIG. 4 is an exploded view of the IP miniature computing unit of the present invention; and

FIG. 5 is a perspective view of the IP miniature computing unit of the present invention.

### DETAILED DESCRIPTION OF THE PREFERRED EMBODIMENTS

Advantages and features of the inventive concept and methods of accomplishing the same may be understood more readily by reference to the following detailed description of embodiments and the accompanying drawings. The inventive concept may, however, be embodied in many different forms and should not be construed as being limited to the embodiments set forth herein. In the drawings, the relative sizes of elements should not be construed as being limited to the proportion and arrangement relationship as shown in the drawings and may be exaggerated for clarity, without departing from the spirit and scope of the present invention.

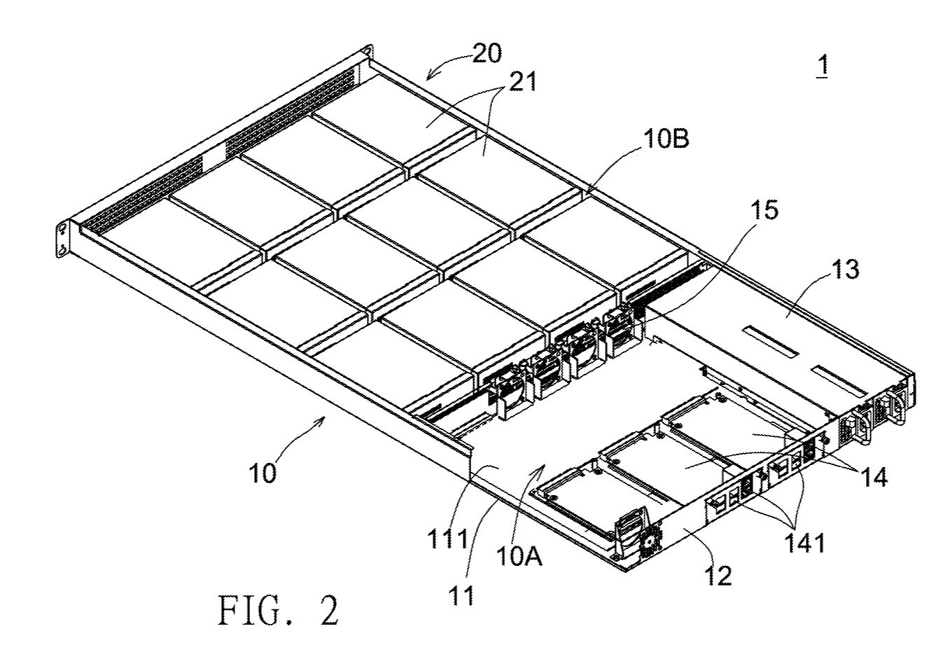

Referring to FIG. 2, the present invention discloses a server having an IP miniature computing unit, which is operated under SDN (software-defined networking). The server 1 has a height of 4.445 cm (1 U). The server 1 comprises a machine body device 10 and electronic devices electrically connected with the machine body device 10. The electronic devices comprise an IP miniature computing device 20, a power supply 13, and a plurality of exchangers 14. The machine body device 10 includes a bottom plate 11 and an end plate 12. The bottom plate 11 is provided with a circuit board 111 thereon. The circuit board 111 and the bottom plate 11 are configured to receive the aforementioned devices and formed with a first receiving space 10A and a second receiving space 10B. A plurality of fans 15 is provided at the junction of the first receiving space 10A and the second receiving space 10B for cooling the IP miniature computing device 20. The power supply 13 and the plurality of switches 14 are disposed in the first receiving space 10A and are electrically connected with the circuit board 111, respectively. Each switchers 14 is provided with a plurality of network interfaces 141. The network interfaces 141 pass through corresponding windows (not numbered) of the end plate 12 to communicate with the outside.

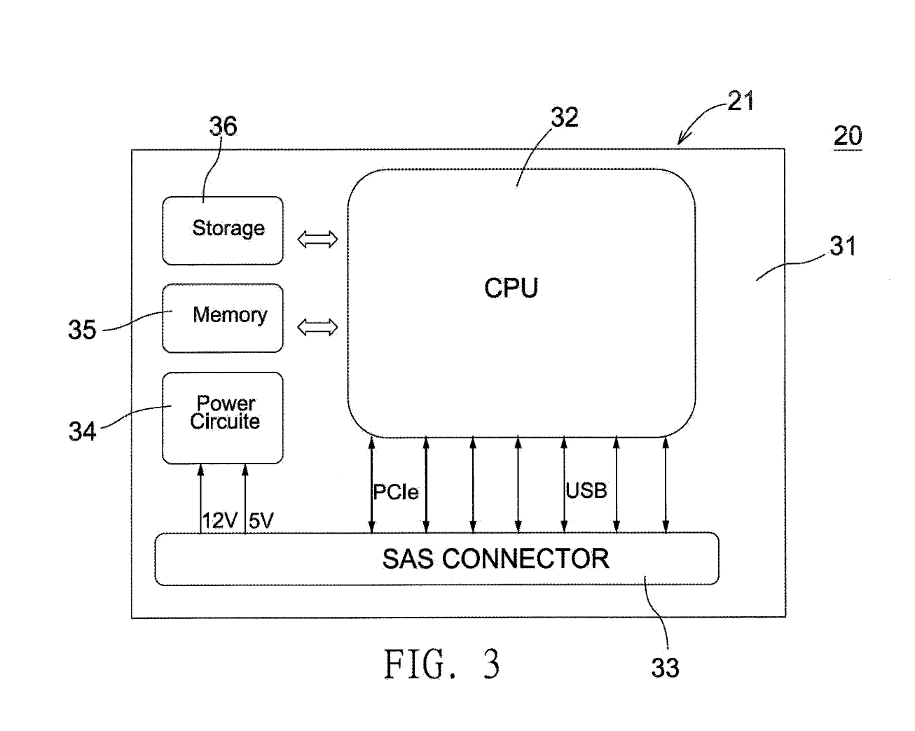

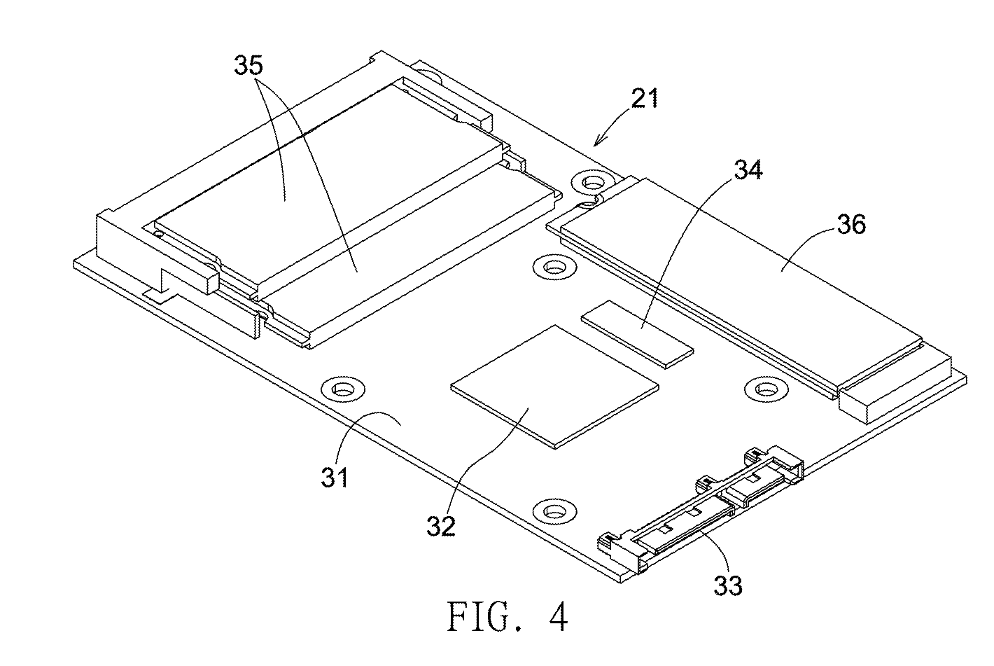

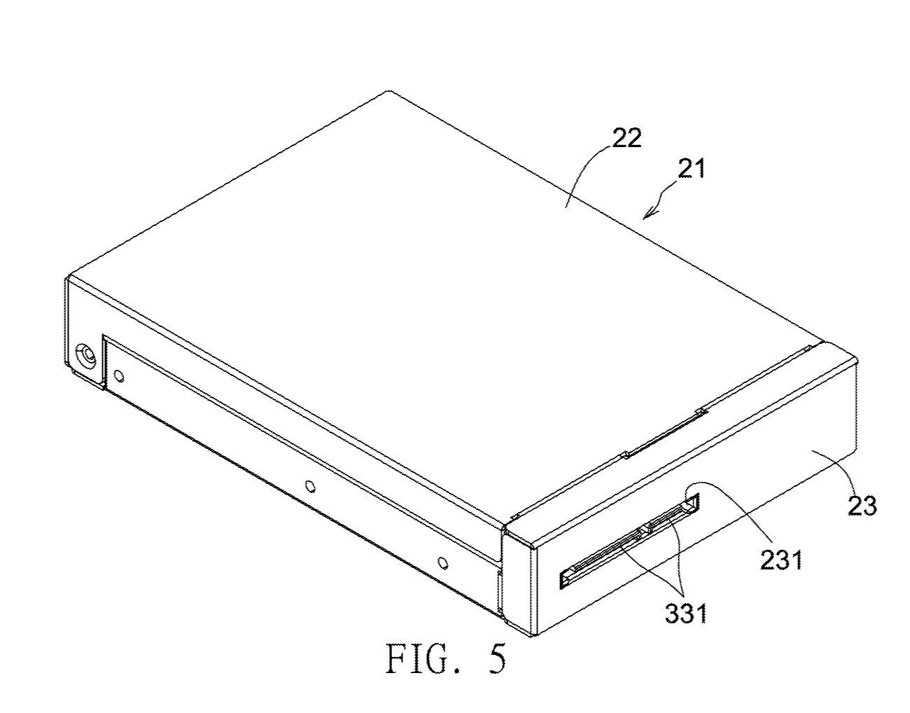

Referring to FIG. 3, FIG. 4 and FIG. 5, the IP miniature computing device 20 is disposed in the second receiving space 10B of the bottom plate 11. The IP miniature computing device 20 includes a plurality of IP miniature computing units 21. Each IP miniature computing unit 21 has its own IP address (Internet Protocol Address), and transmits and receives network signals through the network. The IP miniature computing unit 21 includes a motherboard 31. The motherboard 31 is electrically connected with a processor 32 (CPU or GPU/graphics processor), a SAS connector 33, a voltage converter 34, at least one memory 35, and at least one storage 36. The processor 32 may be a CPU or a GPU (graphics processor). For example, the CPU is an Intel X86 CPU or an ARM base CPU. A heat sink (not shown) is provided above the processor 32. The SAS connector 33 may be a SFF-8323 SAS connector for receiving and transmitting network signals and power. The SAS connector 33 may be communicated with the processor 32 via a PCIe or USB signal, but not limited thereto. The SAS connector 33 has a terminal 331 for providing the SGMII signal to the outside so that the server 1 may be directly connected with the Ethernet network to become a network miniature computing unit. The voltage converter 34 is electrically connected with the SAS connector 33. The voltage converter 34 is used for converting the power received by the SAS connector 33 (5V, 12V) into the voltage required for all the electronic components on the motherboard 31. The memory 35 is DDR3 DRAM or DDR2 DRAM. The storage 36 may be M.2. The M.2 is a specification for internally mounted computer expansion cards and associated connectors, also known as the NGFF (Next Generation Form Factor). The current development trend of the storage is based on the pursuit of access speed, capacity, low power consumption, small size, fast transmission and other characteristics. The M.2/NGFF specification fully supports the current mainstream SATA and PCIe interfaces and replaces the common mSATA interface. For example, the M.2 is always used to an alternative upgrade of Mini PCIe/mSATA for wireless network cards, 3G network cards and some small SSDs, having the advantages of small size, small in height, high integration. Thus, in this embodiment, the server has twelve IP miniature computing units 12.

Referring to FIG. 5, the IP miniature computing unit 21 has a casing 22 for loading the related electronic components of the IP miniature computing unit 21, so that the IP miniature computing unit 21 becomes a hard disk device having an external specification identical to that of a 3.5-inch hard disk. The casing 22 has an end face 23. The end face 23 is provided with an end face interface 231. The end face interface 231 corresponds to the SAS connector 33, so that the terminal 331 of the SAS connector 33 is able to communicate with the external message through the end interface 231.

The advantages of the server having an IP miniature computing unit of the present invention are described hereinafter. At least one storage of the original IP storage server operated under SDN is replaced with the IP miniature computing unit, thereby increasing the computing capability of the IP storage server. Only the IP storage is replaced with the IP miniature computing unit, so the conversion is simple and the cost is very low. Furthermore, the second receiving space 10B of the bottom plate 11 is provided with the plurality of IP miniature computing units 21 (e.g., twelve IP miniature computing units 21). That is, the casing having a height of 1 U is provided with twelve 3.5-inch IP miniature computing units 21 to achieve the technical solution of a high-density rack-mounted server. When one of the IP miniature computing units is damaged, the loss can be reduced. It is convenient to replace the IP miniature computing unit, with excellent practicality and economy.

Thereby, the server having an IP miniature computing unit of the present invention, operated under SDN, uses a 3.5-inch hard disk designed as a 3.5-inch IP miniature computing unit and provides the SGMII signal to the outside through the SAS connector, so that the 3.5-inch IP miniature computing unit can be installed to the existing IP HDD casing. The original network storage is converted into a high-density network miniature computing unit, meeting the requirements of high-density network miniature computing units for cluster servers.

Although particular embodiments of the present invention have been described in detail for purposes of illustration, various modifications and enhancements may be made without departing from the spirit and scope of the present invention. Accordingly, the present invention is not to be limited except as by the appended claims.

What is claimed is:

1. A server having an IP miniature computing unit, operated under SDN (software-defined networking), comprising a machine body device, the machine body device including a bottom plate, the bottom plate being provided with a plurality of electronic devices electrically connected with the bottom plate, the electronic devices including:
at least one power supply;
at least one switch, the switch being provided with a plurality of network interfaces;
an IP miniature computing device, the IP miniature computing device including at least one IP miniature computing unit, the IP miniature computing unit including a motherboard, the motherboard being electrically connected with a processor, at least one SAS connector, a voltage converter, at least one storage, and at least one memory, the SAS connector being used for receiving and transmitting network signals and power, the voltage converter converting the power received by the SAS connector into the voltage required for all electronic components on the motherboard.

2. The server as claimed in claim 1, wherein the SAS connector of the IP miniature computing unit is a SFF-8323 SAS connector.

3. The server as claimed in claim 1, wherein the IP miniature computing unit has an external specification identical to that of a 3.5-inch hard disk.

4. The server as claimed in claim 1, wherein the server has a height of 4.445 cm.

5. The server as claimed in claim 1, wherein the IP miniature computing device includes twelve IP miniature computing units.

6. The server as claimed in claim 1, wherein the storage of the IP miniature computing unit is M.2.

7. The server as claimed in claim 6, wherein the memory of the IP miniature computing unit is DDR3 DRAM or DDR2 DRAM.

8. The server as claimed in claim 1, wherein the processor is a CPU or a GPU (graphics processor), and a heat sink is provided above the processor.

9. The server as claimed in claim 8, wherein the CPU is an Intel X86 CPU or an ARM base CPU.

10. The server as claimed in claim 1, wherein the bottom plate is provided with a circuit board and a plurality of fans thereon.
